(19) United States
(12) Patent Application Publication
(10) Pub. No.: US 2024/0332153 A1
(43) Pub. Date: Oct. 3, 2024

(54) DRY SEED REMOVAL BY LASER FOR LINE-SPACE AND VIA FORMATION

(71) Applicant: Intel Corporation, Santa Clara, CA (US)

(72) Inventors: Tchefor NDUKUM, Chandler, AZ (US); Yonggang LI, Chandler, AZ (US); Rengarajan SHANMUGAM, Tempe, AZ (US); Darko GRUJICIC, Chandler, AZ (US); Deniz TURAN, Chandler, AZ (US)

(21) Appl. No.: 18/129,880

(22) Filed: Apr. 2, 2023

(51) Int. Cl. H01L 23/498; H01L 21/48; H01L 23/15

(52) U.S. Cl. CPC H01L 23/49838; H01L 21/486; H01L 21/4864; H01L 23/15; H01L 23/49827; H01L 23/49866

(57) ABSTRACT

Embodiments disclosed herein include electronic packages. In an embodiment, the electronic package comprises a substrate and a seed layer over the substrate. In an embodiment, sidewalls of the seed layer are sloped. In an embodiment, the electronic package further comprises a feature over the seed layer, where the feature is electrically conductive.

### TECHNICAL FIELD

Embodiments of the present disclosure relate to electronic systems, and more particularly to electronic packages with conductive features that are formed with a laser ablation patterning of the seed layer.

### BACKGROUND

Advanced electrical packaging architectures continue to grow more complex as products continue to scale to smaller sizes while also incorporating more electrical routing. The additional routing is needed in order to meet the high bandwidth and increasing load demands of newer applications. The many layers and increasing number of components that are incorporated into each electronic package has led to a significant increase in the cost of advanced electronics packages. One of the most expensive sections of a typical substrate package fabrication process is the lithography loop. Further, since the lithography loop needs to be repeated for each routing layer, costs can quickly increase as the number of layers increase.

The lithography loop incorporates many sub-operations, with each sub-operation increasing costs and manufacturing duration. For example, the lithography loop may consist of a seed layer deposition and annealing operation. A dry film resist (DFR) is then deposited over the seed layer. The DFR is then exposed to form a latent image in the DFR. The latent image can then be developed to form a pattern in the DFR. After cleaning operations, a plating process can then be implemented to plate copper over regions of the seed layer that are exposed by the pattern in the DFR. A resist stripping process is use to remove the DFR. A seed etching process (e.g., a flash etching process) can then be done to remove residual portions of the seed layer.

### BRIEF DESCRIPTION OF THE DRAWINGS

FIG. 1 is a process flow diagram of a lithography loop used in the manufacture of electronic packages, in accordance with an embodiment.

FIG. 2 is a process flow diagram of a streamlined laser assisted plating process that can be used in the manufacture of electronic packages, in accordance with an embodiment.

FIG. 3A is a cross-sectional illustration of an electronic package at a stage of manufacture, in accordance with an embodiment.

FIG. 3B is a cross-sectional illustration of the electronic package after a seed layer is provided over a topmost dielectric layer, in accordance with an embodiment.

FIG. 3C is a cross-sectional illustration of the electronic package after a laser is used to selectively remove portions of the seed layer, in accordance with an embodiment.

FIG. 3D is a cross-sectional illustration of the electronic package after conductive features are plated over the seed layer, in accordance with an embodiment.

FIG. 4A is a zoomed in cross-sectional illustration of a conductive feature with a seed layer that includes non-vertical sidewalls, in accordance with an embodiment.

FIG. 4B is a zoomed in cross-sectional illustration of a conductive feature with a seed layer and a recessed dielectric layer, in accordance with an embodiment.

FIG. 5A is a cross-sectional illustration of a glass core with via openings and a seed layer, in accordance with an embodiment.

FIG. 5B is a cross-sectional illustration of the glass core during a laser ablation process, in accordance with an embodiment.

FIG. 5C is a cross-sectional illustration of the glass core after the seed layer is patterned, in accordance with an embodiment.

FIG. 5D is a cross-sectional illustration of the glass core after conductive material is plated over the seed layer, in accordance with an embodiment.

FIG. 6A is a cross-sectional illustration of a core with a buffer layer over the core, in accordance with an embodiment.

FIG. 6B is a cross-sectional illustration of the core after a seed layer is applied over the buffer layer, in accordance with an embodiment.

FIG. 6C is a cross-sectional illustration of the core during a laser ablation process, in accordance with an embodiment.

FIG. 6D is a cross-sectional illustration of the core after a conductive material is plated over the seed layer, in accordance with an embodiment.

FIG. 7A is a cross-sectional illustration of a dielectric buildup layer with a seed layer, in accordance with an embodiment.

FIG. 7B is a cross-sectional illustration of the buildup layer during laser ablation of the seed layer, in accordance with an embodiment.

FIG. 7C is a cross-sectional illustration of the buildup layer after the seed layer is patterned, in accordance with an embodiment.

FIG. 7D is a cross-sectional illustration of the buildup layer after a conductive material is plated over the seed layer, in accordance with an embodiment.

FIG. 8 is a cross-sectional illustration of an electronic system with a package substrate that includes a seed layer that has been patterned by laser ablation, in accordance with an embodiment.

FIG. 9 is a schematic of a computing device built in accordance with an embodiment.

### EMBODIMENTS OF THE PRESENT DISCLOSURE

Described herein are electronic systems, and more particularly electronic packages with conductive features that are formed with a laser ablation patterning of the seed layer, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

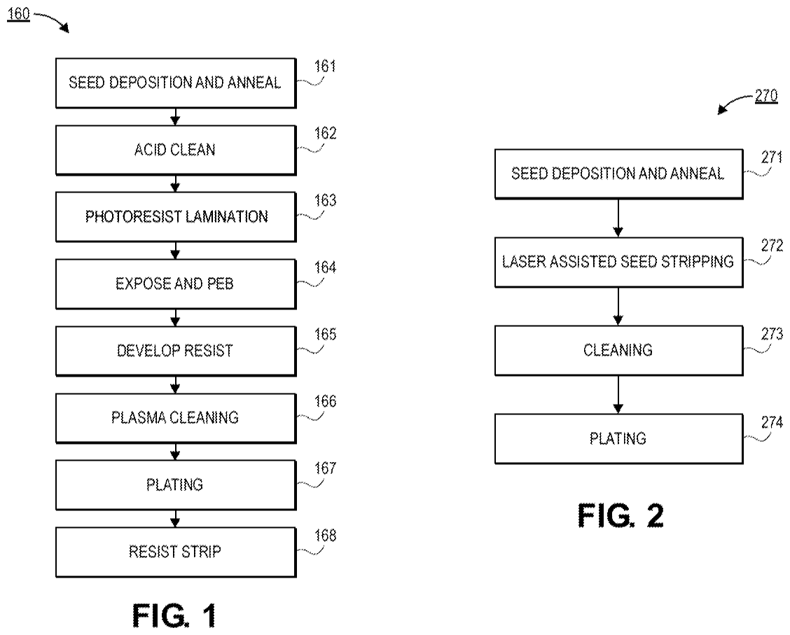

As noted above, the lithography loop of electronic package manufacturing is a costly and time consuming operation. For example, a sample process flow 160 for a lithography loop is illustrated in FIG. 1. The process flow 160 may begin with operation 161 which includes seed deposition and annealing processes. The seed layer is deposited with a blanket deposition process over the entire substrate. After the seed layer deposition, the process flow 160 may continue with operation 162, which includes an acid cleaning operation. Process flow 160 may then continue with operation 163 which includes photoresist lamination. For example, the photoresist lamination may include laminating and pressing a dry film resist (DFR) over the seed layer. Though other photosensitive materials (e.g., liquid resists) may also be used. Process flow 160 then proceeds to operation 164 which includes an exposure and post exposure bake (PEB) of the DFR. After exposure, operation 165 includes developing the resist. The developing process may be followed by a plasma cleaning at operation 166. After the cleaning, a plating process is done at operation 167 in order to plate the electrically conductive features. A resist stripping process is then implemented at operation 168 in order to remove the DFR. Thereafter, a seed etching process (e.g., a flash etching process) may be used to remove residual portions of the seed layer.

As can be appreciated, such processing operations involve the transfer of the substrate between multiple different tools. The large number of tools (e.g., exposure tool, develop tool, plasma tool, etc.) leads to a high total cost of ownership due to the need to maintain and operate each of the different tools. Repeating the lithography loop for each routing layer significantly increases the overall cost of the electronic package.

Accordingly, embodiments disclosed herein include alternative process flows that avoid the use of a DFR or other photoresist material. Instead, the seed layer is directly patterned with a laser ablation process. For example, an excimer laser is used in order to remove portions of the seed layer where conductive material is not wanted. The patterned seed layer can then be used in order to plate up the conductive features (e.g., vias, pads, traces, etc.). For example, an electroless plating process may be used to plate up the conductive features. The laser ablation process may be done with a mask or with a maskless process. While referred to generally as a seed layer, it is to be appreciated that any metallic layer may be used as a seed layer. For example, the metallic layer may comprise one or more of palladium, titanium, and copper.

Further, it is to be appreciated that the laser ablation process may result in characteristic features that persist into the final structure of the device. For example, the laser ablation process may result in the sidewalls of the seed layer being non-vertical. For example, the sidewall slopes from the top edge out towards the bottom edge. This is in contrast to the profile of a wet etching process, which may result in a seed layer that has an undercut. Additionally, depending on the material of the substrate, the laser ablation process may slightly damage the surface or recess the surface. For example, recesses adjacent to the metal features may be up to approximately 2 μm or more in some embodiments.

Referring now to FIG. 2, a process flow 270 using a laser ablation patterning solution is shown, in accordance with an embodiment. In an embodiment, the process flow 270 may begin with operation 271, which comprises depositing a seed layer and implementing an anneal of the seed layer. The seed layer may be any suitable seed layer material, such as a material comprising one or more of palladium, titanium, and copper. The seed layer may be deposited with a blanket deposition process. That is, the seed layer may be provided over the entire exposed surface of the underlying substrate, including in via openings. The seed layer may also be referred to as a metallic layer.

In an embodiment, the process flow 270 may continue with operation 272, which comprises a laser assisted seed stripping process. The laser assisted seed stripping process may utilize any suitable laser, such as an excimer laser. A mask may be used to only allow the laser to reach the seed layer in locations where the seed layer needs to be removed. While a mask layer allows for improved resolution, a maskless solution may be used when larger line/space dimensions are needed. The use of laser ablation may result in physical signatures that may be used to demonstrate use of a process similar to the described with respect to process flow 270. For example, residual edges of the seed layer may be tapered (i.e., outwardly tapered from top to bottom), and the underlying substrate may be recessed (e.g., up to approximately 2 μm or more).

In an embodiment, the process flow 270 may continue with operation 273, which comprises a cleaning process. The cleaning may be implemented using a plasma cleaning process. After the cleaning operation 273, the process flow 270 may continue with operation 274, which comprises plating the conductive features. Since a continuous electrical circuit is not present (because the seed layer is patterned) the plating process may include an electroless plating process in some embodiments. The conductive features that are plated may include pads, traces, vias, and the like.

The process flow 270 is described as being implemented on a generic substrate. However, it is to be appreciated that process flow 270 may be implemented at various layers of a package substrate. For example, the process flow 270 may be implemented on a core (e.g., a glass core or an organic core), a buffer layer over a core, or a buildup layer of the package substrate. Accordingly, embodiments allow for process flow 270 to be implemented throughout the manufacturing process used to form a package substrate.

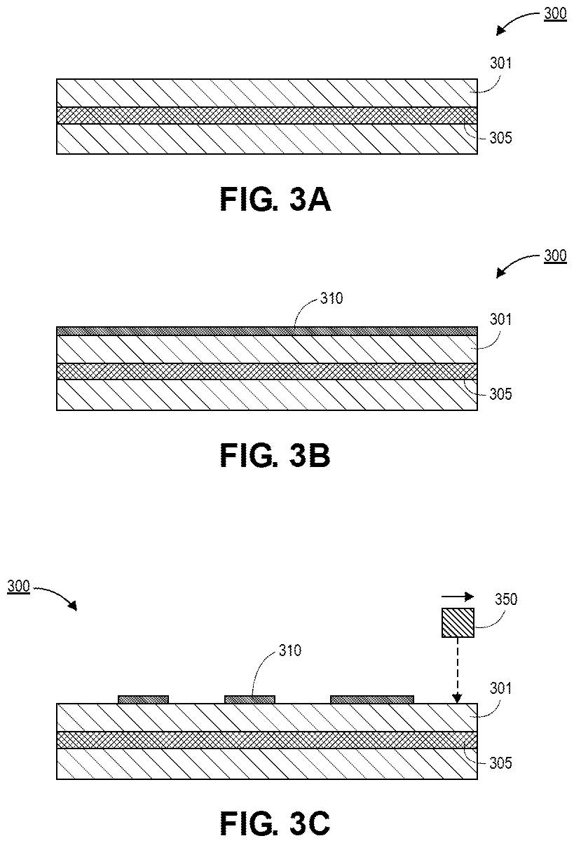

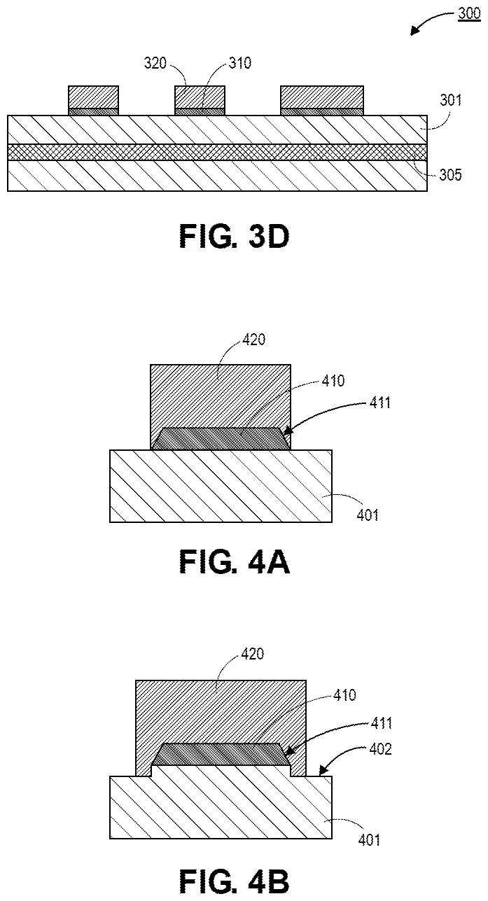

Referring now to FIGS. 3A-3D, a series of cross-sectional illustrations depicting a process for fabricating a package substrate 300 with a laser assisted patterning process similar to process flow 270 is shown, in accordance with an embodiment.

Referring now to FIG. 3A, a cross-sectional illustration of a package substrate 300 at a stage of manufacture is shown, in accordance with an embodiment. In an embodiment, the package substrate 300 may comprise a core 305. The core 305 may be a glass core, an organic core, or any other suitable core material. When the core 305 is a glass core, it is to be appreciated that one or more layers of glass are provided. That is, a glass core is different than an organic core that may have glass fiber reinforcement. Buildup layers 301 may be provided above and below the core 305. The buildup layers 301 may comprise an organic buildup film or the like. Multiple layers of buildup film may be laminated over each other. A routing layer may be provided on each of the buildup layers 301, and vias may provide connections between the buildup layers 301.

Referring now to FIG. 3B, a cross-sectional illustration of the package substrate 300 after a seed layer 310 is deposited over the top buildup layer 301 is shown, in accordance with an embodiment, the seed layer 310 may be deposited with any suitable blanket deposition process. For example, chemical vapor deposition (CVD), atomic layer deposition (ALD), or physical vapor deposition (PVD) may be used to deposit the seed layer 310. In an embodiment, the seed layer 310 may include any suitable seed layer material. For example, the seed layer 310 may comprise one or more of palladium, titanium, and copper. The seed layer 310 may have a thickness that is approximately 1 μm or less. In a particular embodiment, the seed layer 310 may have a thickness that is approximately 100 nm or less. As used herein, “approximately” may be used to refer to a range of values within ten percent of the stated value. For example, approximately 100 nm may refer to a range between 90 nm and 110 nm.

Referring now to FIG. 3C, a cross-sectional illustration of the package substrate 300 during a seed layer 310 patterning operation is shown, in accordance with an embodiment. In an embodiment, the seed layer 310 is patterned using a laser 350. The laser 350 may scan across the package substrate 300 (as indicated by the horizontal arrow). The laser 350 may emit a laser beam (indicated by the dashed arrow) that ablates the seed layer 310. Any suitable laser 350 may be used to ablate the seed layer 310. For example, the laser 350 may be an excimer laser. The laser 350 may ablate seed layer 310 without a mask layer in some embodiments. However, a mask (not shown) with patterned openings may also be used. The use of a mask may improve the possible resolution of the patterning process.

Referring now to FIG. 3D, a cross-sectional illustration of the package substrate 300 after a plating process is shown, in accordance with an embodiment. The plating process may be used to plate up conductive features 320 over the patterned seed layer 310. In an embodiment, the conductive features 320 may include traces and/or pads. The conductive features may have a thickness that is approximately 10 μm or less in some embodiments. The plating process used in FIG. 3D may be an electroless plating process. An electroless process may be used since the conductive features 320 are not electrically coupled together by a continuous seed layer 310.

After plating the conductive features 320, the package substrate 300 may continue with standard package assembly processes. For example, another buildup layer 301 may be provided over the conductive features 320. A second routing layer and vias may then be formed over and/or through the additional buildup layer 301. This process may repeat until the desired number of buildup layers 301 are provided in the package substrate 300.

Referring now to FIGS. 4A and 4B, a pair of zoomed in cross-sectional illustrations of a pair of conductive features 420 over a buildup layer 401 is shown, in accordance with an embodiment. Particularly, the embodiments shown in FIGS. 4A and 4B illustrate the structure of the seed layer 410 and the neighboring surface of the buildup layer 401. The particular architectures shown in FIGS. 4A and 4B may be indicative of a laser ablation patterning process used to pattern the seed layer, in accordance with various embodiments.

Referring now to FIG. 4A, a cross-sectional illustration of a conductive feature 420 over a buildup layer 401 is shown, in accordance with an embodiment. In an embodiment, the conductive feature 420 may be a pad or a trace. The conductive feature 420 may be plated up from a seed layer 410. The seed layer 410 may comprise any suitable material, such as one comprising one or more of palladium, titanium, and copper. The seed layer 410 may be patterned with a laser ablation process. The laser ablation process may result in sidewalls 411 that are non-vertical. For example, the sidewalls 411 may be outwardly sloping so that a bottom of the seed layer 410 is wider than a top of the seed layer 410. In contrast, a sidewall 411 that is defined by a traditional wet etching process would be inward sloping, or otherwise include an undercut. The conductive feature 420 may contact the entire top surface of the seed layer 410 and the sidewalls 411 of the seed layer 410 in some embodiments.

Referring now to FIG. 4B, a cross-sectional illustration of a conductive feature 420 is shown in accordance with an additional embodiment. The structure in FIG. 4B may be substantially similar to the structure shown in FIG. 4A, with the exception of the top surface 402 of the buildup layer 401. As shown, the top surface 402 may be recessed below a bottom surface of the seed layer 410. This recess may be the result of a laser ablation process. That is, the laser ablation process may remove the seed layer 410 and a portion of the underlying buildup layer 401. For example, the recess of the top surface 402 may be up to approximately 2 μm. Though, larger recesses may also be provided in some embodiments. As shown, the conductive feature 420 may extend past the sidewalls 411 of the seed layer 410 and contact a portion of the recessed top surface 402. That is, a width of the conductive feature 420 may be wider than a width of the seed layer 410 in some embodiments.

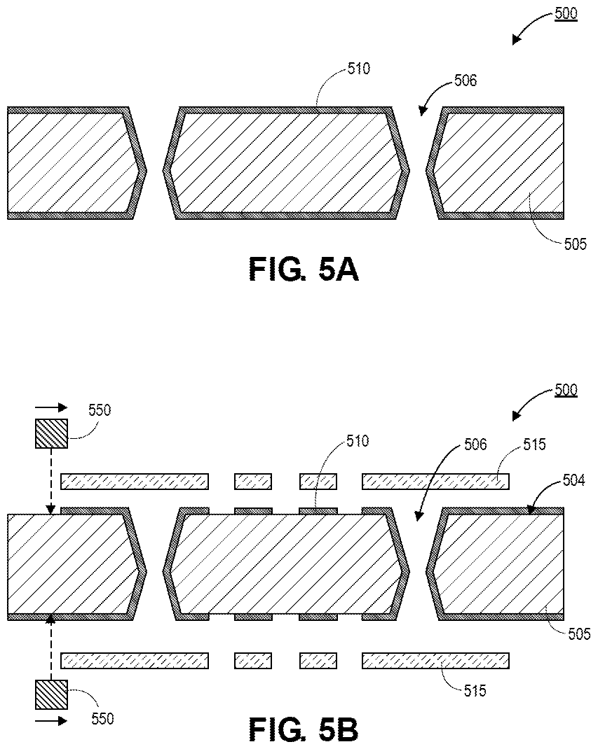

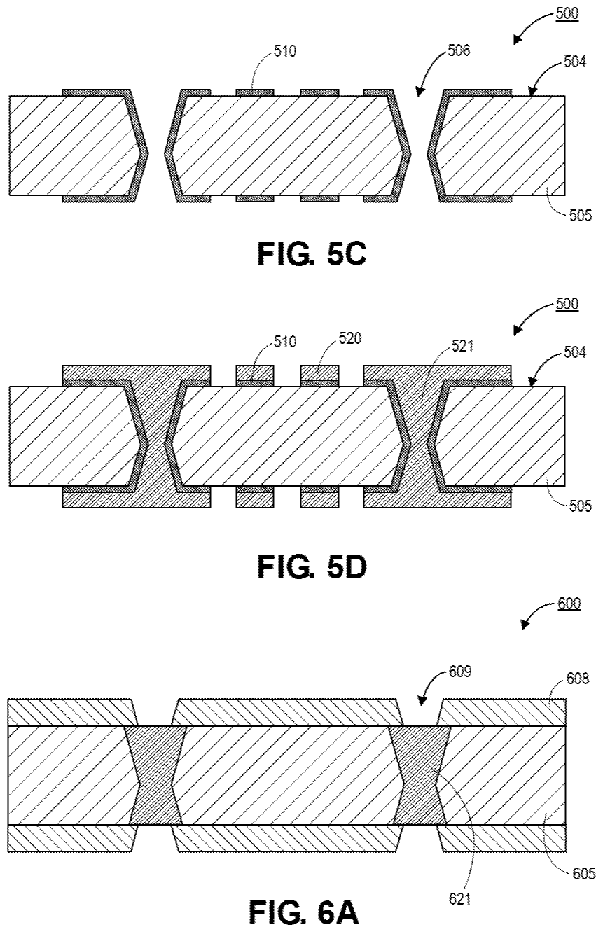

Referring now to FIGS. 5A-5D, a series of cross-sectional illustrations depicting a process for forming conductive features on and/or through a core 505 is shown, in accordance with an embodiment. In some embodiments, the core 505 may be a glass core. Though, organic cores 505 may also be used in some embodiments.

Referring now to FIG. 5A, a cross-sectional illustration of a package substrate 500 at a stage of manufacture is shown, in accordance with an embodiment. In an embodiment, the package substrate 500 may comprise a core 505, such as a glass core 505 or an organic core 505. In an embodiment, via openings 506 are provided through a thickness of the core 505. In the case of a glass core 505, the via openings 506 may be formed with a laser assisted patterning process. That is, a laser may expose regions of the core 505 in order to modify the microstructure and/or phase of the core 505. Thereafter a wet etching process may selectively remove the modified regions of the core 505. As shown, the via opening 506 may have an hourglass shaped cross-section. Though, in the case of thinner cores 505, a single slope may be included in the via openings 506.

In an embodiment, a seed layer 510 may be applied over surfaces of the core 505 after the via openings 506 are formed. The seed layer 510 may line the top surface and the bottom surface of the core 505. Additionally, the seed layer 510 may line the via openings 506. The seed layer 510 may be deposited with any suitable deposition process, (e.g., CVD, ALD, PVD, etc.). The seed layer 510 may comprise one or more of palladium, titanium, and copper. A thickness of the seed layer 510 may be approximately 1 μm or less, or approximately 100 nm or less.

Referring now to FIG. 5B, a cross-sectional illustration of the package substrate 500 during a laser ablation process is shown, in accordance with an embodiment. As indicated by horizontal arrows, lasers 550 scan across the top and bottom surfaces of the core 505. The laser 550 emits electromagnetic radiation (as indicated by the dashed lines) that ablates exposed portions of the seed layer 510. The laser 550 may be an excimer laser or any other suitable laser. The laser 550 may pass over a mask 515. Openings in the mask 515 may be located above portions of the core 505 where the seed layer 510 needs to be ablated. While shown as having both a top laser 550 and a bottom laser 550, a single laser may be used for the top and bottom surfaces in some embodiments.

Referring now to FIG. 5C, a cross-sectional illustration of the package substrate 500 after the laser ablation process is shown, in accordance with an embodiment. As shown, the laser ablation may result in the exposure of portions of the top and bottom surfaces 504 of the core 505. The residual portions of the seed layer 510 may be provided at locations where conductive features are desired. For example, pads or traces may be provided over the surfaces 504 of the core 505, and portions of the seed layer 510 may line the via openings 506 in order to plate up vias through the core 505. In an embodiment, the seed layer 510 may have a shape similar to the seed layer shown in FIG. 4A. That is, the edges of the seed layer 510 may be non-vertical and outward sloping.

Referring now to FIG. 5D, a cross-sectional illustration of the package substrate 500 after a plating process is shown, in accordance with an embodiment. In an embodiment, the plating process may form conductive features 520 over the seed layer 510. Additionally, the plating may form vias 521 through the core 505. The vias 521 may have hourglass shaped cross-sections in some embodiments. In an embodiment, the plating process may be an electroless plating process since the conductive features are electrically isolated from each other and are not connected by an underlying seed layer 510.

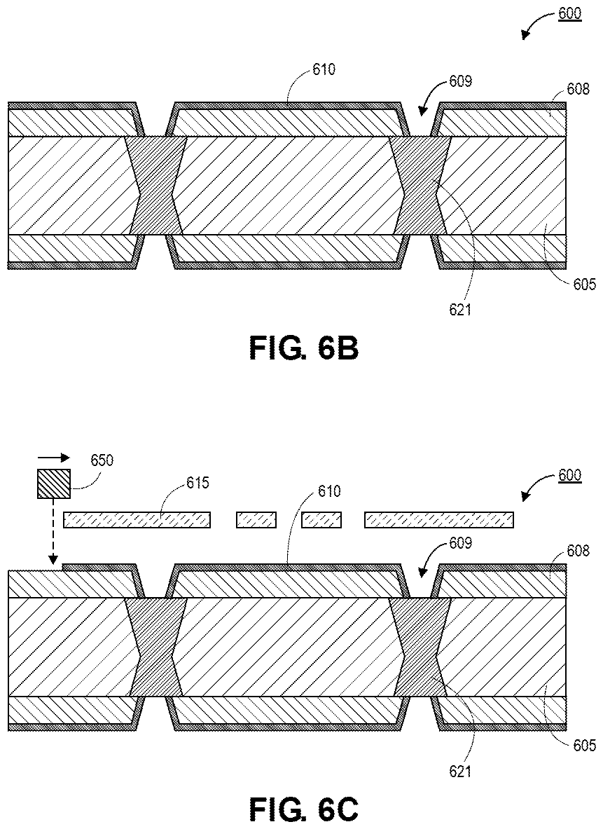

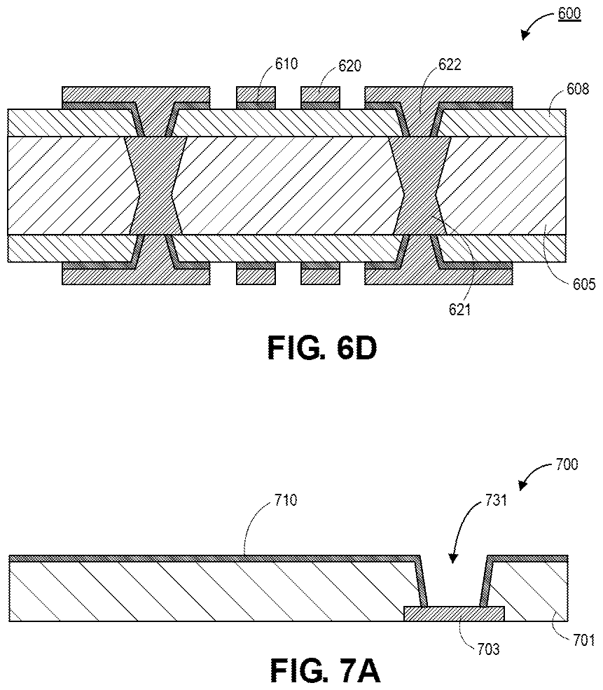

Referring now to FIGS. 6A-6D, a series of cross-sectional illustrations depicting a process for forming conductive features over a buffer layer 608 on a core 605 is shown, in accordance with an embodiment.

Referring now to FIG. 6A, a cross-sectional illustration of a package substrate 600 at a stage of manufacture is shown, in accordance with an embodiment. The package substrate 600 may comprise a core 605 (e.g., a glass core 605 or an organic core 605). Vias 621 may be provided through a thickness of the core 605. In an embodiment, buffer layers 608 may be provided over and under the core 605. The buffer layers 608 may comprise an insulating material, such as one comprising silicon and oxygen. In an embodiment, via openings 609 may be provided through the buffer layers 608. The via openings 609 may be aligned over vias 621. In an embodiment, the via openings 609 may have tapered sidewalls.

Referring now to FIG. 6B, a cross-sectional illustration of the package substrate 600 after a seed layer 610 is deposited is shown, in accordance with an embodiment. In an embodiment, the seed layer 610 may comprise one or more of palladium, titanium, and copper. A thickness of the seed layer 610 may be approximately 1 μm or less, or approximately 100 nm or less. In an embodiment, the seed layer 610 may be applied with any suitable blanket deposition process (e.g., CVD, ALD, PVD, etc.). In an embodiment, the seed layer 610 may be provided over the horizontal surfaces of the buffer layer 608 and along sidewalls of the via openings 609.

Referring now to FIG. 6C, a cross-sectional illustration of the package substrate 600 during a seed layer 610 patterning operation is shown, in accordance with an embodiment. As shown, a laser 650 may be scanned across the surface of the package substrate 600. The laser 650 may emit electromagnetic radiation (indicated by the dashed arrow) that ablates exposed portions of the seed layer 610. A mask 615 may be provided between the laser 650 and the package substrate 600. The mask 615 may include openings that are located where a seed layer 610 is not desired. Though, in some embodiments, a maskless patterning operation may also be used at the cost of lower resolution. As shown in FIG. 6C, the laser 650 is provided over the top surface of the package substrate 600. Though, it is to be appreciated that the bottom surface of the package substrate 600 may be patterned in a similar fashion.

Referring now to FIG. 6D, a cross-sectional illustration of the package substrate 600 after a plating process is shown, in accordance with an embodiment. In an embodiment, the plating process may be implemented after the seed layer 610 is fully patterned. In an embodiment, the patterning process may result in the sidewalls of the seed layer 610 being outwardly sloping, similar to the embodiment shown in FIG. 4A. Additionally, the buffer layer 608 may be recessed, similar to the embodiment shown in FIG. 4B. In an embodiment, the plating process may result in the formation of conductive features 620 (e.g., pads, traces, etc.) and vias 622.

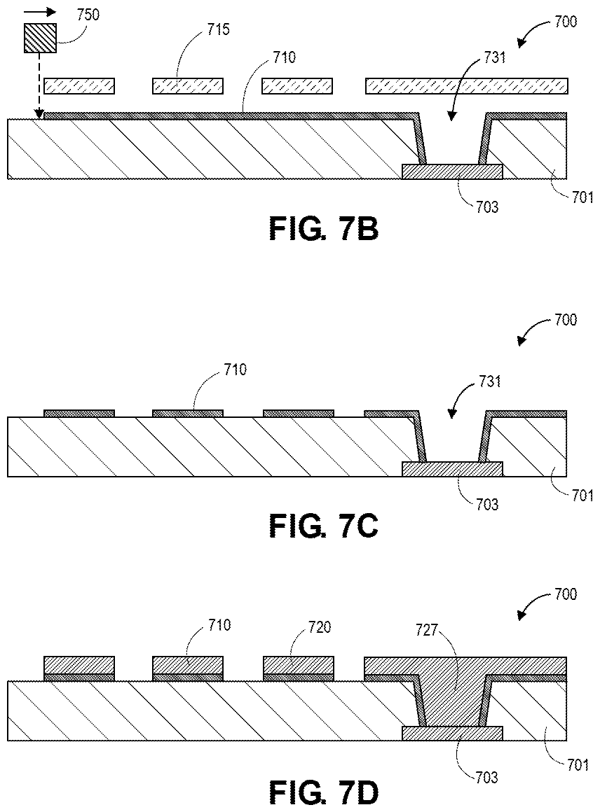

Referring now to FIGS. 7A-7D, a series of cross-sectional illustrations depicting the formation of conductive features on a buildup layer 701 in a package substrate 700 is shown, in accordance with an embodiment. In the illustrated embodiment, a single buildup layer 701 is shown in isolation. However, it is to be appreciated that the buildup layer 701 may be provided over a core (not shown) or over other buildup layers (not shown).

Referring now to FIG. 7A, a cross-sectional illustration of a package substrate 700 at a stage of manufacture is shown, in accordance with an embodiment. In an embodiment, the package substrate 700 may comprise a buildup layer 701. The buildup layer 701 may be an organic buildup film or the like. In an embodiment, the buildup layer 701 may be provided over other buildup layers or a core (not shown). In an embodiment, a pad 703 may be provided at a bottom of the buildup layer 701. A via opening 731 may be provided through the buildup layer 701 in order to expose the pad 703. In an embodiment, a seed layer 710 may be provided over the buildup layer 701. The seed layer 710 may comprise one or more of palladium, titanium, and copper. The seed layer 710 may have a thickness that is approximately 1 μm or less, or approximately 100 nm or less.

Referring now to FIG. 7B a cross-sectional illustration of the package substrate 700 during a seed layer 710 patterning operation is shown, in accordance with an embodiment. As shown, a laser 750 may be scanned across the surface of the package substrate 700. The laser 750 emits electromagnetic radiation (indicated by the dashed arrow) that ablates exposed portions of the seed layer 710. A mask 715 may be provided between the laser 750 and the package substrate 700. The mask 715 may include openings that are located where a seed layer 710 is not desired. Though, in some embodiments, a maskless patterning operation may also be used at the cost of lower resolution.

Referring now to FIG. 7C, a cross-sectional illustration of the package substrate 700 after the seed layer 710 patterning is shown, in accordance with an embodiment. As shown, seed layer 710 may be provided over the top surface of the buildup layer 701 and along sidewalls of the via opening 731. Edges or sidewalls of the seed layer 710 may be non-vertical. For example, the edges or sidewalls may be outwardly sloping, similar to the embodiment shown in FIG. 4A. Additionally, the laser ablation process may result in recessing or damage to the top surface of the buildup layer 701. For example, the buildup layer 701 may be recessed by up to approximately 2 μm in some embodiments.

Referring now to FIG. 7D, a cross-sectional illustration of the package substrate 700 after a plating process is shown, in accordance with an embodiment. In an embodiment, the plating process may result in the formation of conductive features 720 and vias 727. The conductive features 720 may include pads, traces, and the like. In an embodiment, the plating process may be an electroless plating process.

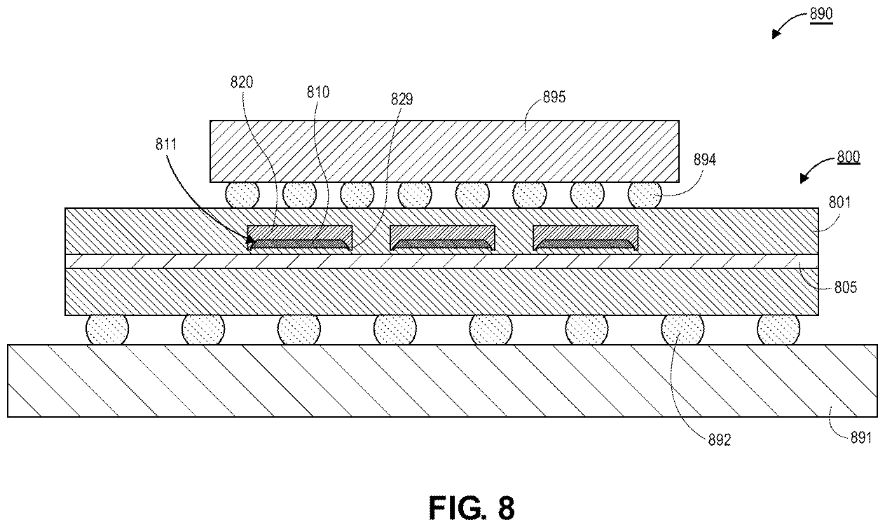

Referring now to FIG. 8, a cross-sectional illustration of an electronic system 890 is shown, in accordance with an embodiment. In an embodiment, the electronic system 890 comprises a board 891, such as a printed circuit board (PCB). The board 891 may be coupled to a package substrate 800 by interconnects 892. The interconnects 892 may comprise solder balls, sockets, or any other suitable interconnect architecture.

In an embodiment, the package substrate 800 may comprise a core 805 with buildup layers 801 above and below the core 805. Conductive features 820 may be provided in the package substrate 800. The conductive features 820 may be provided over seed layers 810. The seed layers 810 may include sidewalls 811 that are non-vertical. For example, the sidewalls 811 may be outwardly sloping, similar to the embodiment shown in FIG. 4A. In an embodiment, portions 829 of the conductive features 820 may wrap around and below the sidewalls 811. For example, a feature similar to the feature shown in FIG. 4B with a recessed buildup layer may be included in the package substrate 800. Conductive features 820 may also include vias (not shown). The conductive features 820 may be provided directly on the core 805, on a buffer layer (not shown) over the core, or on a buildup layer 801.

In an embodiment, one or more dies 895 may be coupled to the package substrate by interconnects 894. The interconnects 894 may be solder balls, copper bumps, or any other first level interconnect (FLI) architecture. The one or more dies 895 may include any type of die, such as a central processing unit (CPU), a graphics processing unit (GPU), an XPU, a system on a chip (SoC), a communications die, or a memory die.

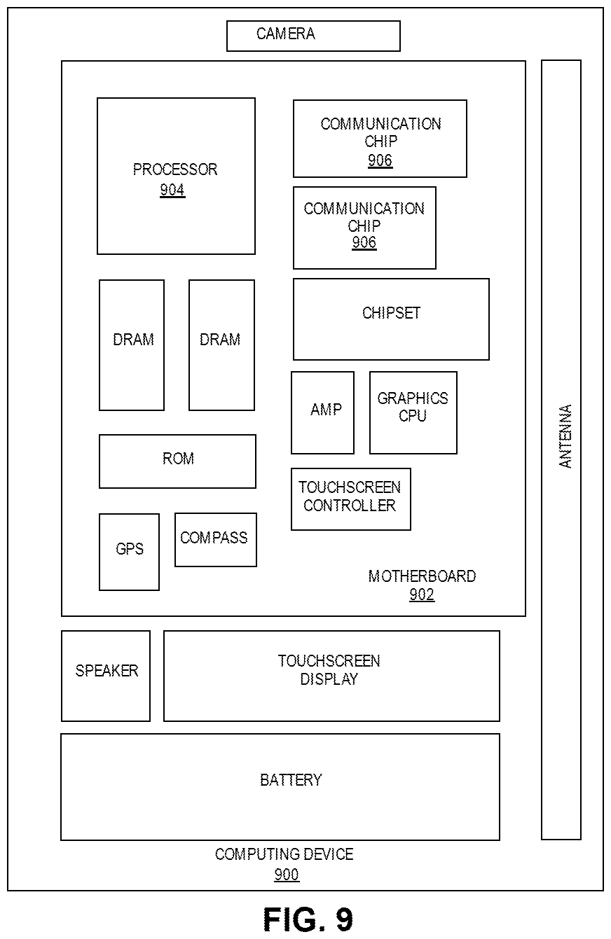

FIG. 9 illustrates a computing device 900 in accordance with one implementation of the invention. The computing device 900 houses a board 902. The board 902 may include a number of components, including but not limited to a processor 904 and at least one communication chip 906. The processor 904 is physically and electrically coupled to the board 902. In some implementations the at least one communication chip 906 is also physically and electrically coupled to the board 902. In further implementations, the communication chip 906 is part of the processor 904.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 906 enables wireless communications for the transfer of data to and from the computing device 900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 906 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 900 may include a plurality of communication chips 906. For instance, a first communication chip 906 may be dedicated to shorter range wireless communications such as Wi-Fi and Bluetooth and a second communication chip 906 may be dedicated to longer range wireless communications such as GPS, EDGE, GPRS, CDMA, WiMAX, LTE, Ev-DO, and others.

The processor 904 of the computing device 900 includes an integrated circuit die packaged within the processor 904. In some implementations of the invention, the integrated circuit die of the processor may be part of an electronic package with a package substrate that includes seed layers with outwardly sloping sidewalls, in accordance with embodiments described herein. The term “processor” may refer to any device or portion of a device that processes electronic data from registers and/or memory to transform that electronic data into other electronic data that may be stored in registers and/or memory.

The communication chip 906 also includes an integrated circuit die packaged within the communication chip 906. In accordance with another implementation of the invention, the integrated circuit die of the communication chip may be part of an electronic package with a package substrate that includes seed layers with outwardly sloping sidewalls, in accordance with embodiments described herein.

In an embodiment, the computing device 900 may be part of any apparatus. For example, the computing device may be part of a personal computer, a server, a mobile device, a tablet, an automobile, or the like. That is, the computing device 900 is not limited to being used for any particular type of system, and the computing device 900 may be included in any apparatus that may benefit from computing functionality.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: an electronic package, comprising: a substrate comprising a glass layer; a metallic layer over the glass layer, the metallic layer comprising one or more of palladium, titanium, and copper, wherein sidewalls of the metallic layer are sloped; and a feature over the metallic layer, wherein the feature is electrically conductive.

Example 2: the electronic package of Example 1, wherein the feature is provided over a top surface of the metallic layer and over the sidewalls of the metallic layer.

Example 3: the electronic package of Example 1 or Example 2, wherein the substrate adjacent to the sidewalls of the metallic layer is recessed.

Example 4: the electronic package of Example 3, wherein the feature extends over the recessed surface of the substrate.

Example 5: the electronic package of Examples 1-4, wherein the feature is a trace.

Example 6: the electronic package of Examples 1-4, wherein the feature is a pad.

Example 7: the electronic package of Examples 1-6, wherein the metallic layer is a seed layer.

Example 8: the electronic package of Examples 1-6, wherein the substrate comprises a buildup layer over the glass layer, and wherein the metallic layer is on the buildup layer.

Example 9: an electronic package, comprising: a core, wherein the core comprises glass; a via through the core, wherein a first seed layer is provided between the via and the core; and traces over the core, wherein a second seed layer is provided between the traces and the core, and wherein sidewalls of the second seed layer are sloped.

Example 10: the electronic package of Example 9, wherein the sidewalls of the second seed layer are sloped so that a bottom of the second seed layer is wider than a top of the second seed layer.

Example 11: the electronic package of Example 9 or Example 10, wherein the via is an hourglass shaped via.

Example 12: the electronic package of Examples 9-11, wherein the first seed layer and the second seed layer comprise one or more of palladium, titanium, and copper.

Example 13: the electronic package of Examples 9-12, further comprising: a buffer layer over the core, wherein the via passes through the buffer layer, and wherein the traces are on the buffer layer.

Example 14: the electronic package of Example 13, wherein the via has tapered sidewalls.

Example 15: the electronic package of Example 13 or Example 14, wherein the buffer layer exhibits laser induced damage on a top surface.

Example 16: the electronic package of Example 15, wherein the buffer layer is recessed approximately 2 μm or more below the second seed layer.

Example 17: an electronic system, comprising: a board; a package substrate coupled to the board, wherein the package substrate comprises: a substrate; a seed layer over the substrate, wherein edges of the seed layer have a non-vertical profile; and a feature over the seed layer, wherein the feature is electrically conductive; and a die coupled to the package substrate.

Example 18: the electronic system of Example 17, wherein the substrate adjacent to the edges of the seed layer is recessed by approximately 2 μm or more.

Example 19: the electronic system of Example 17 or Example 18, wherein the non-vertical profile is an outward slope with a top surface that is narrower than a bottom surface.

Example 20: the electronic system of Examples 17-20, wherein the electronic system is part of a personal computer, a server, a mobile device, a tablet, or an automobile.

What is claimed is:

1. An electronic package, comprising:
a substrate comprising a glass layer;
a metallic layer over the glass layer, the metallic layer comprising one or more of palladium, titanium, and copper, wherein sidewalls of the metallic layer are sloped; and
a feature over the metallic layer, wherein the feature is electrically conductive.

2. The electronic package of claim 1, wherein the feature is provided over a top surface of the metallic layer and over the sidewalls of the metallic layer.

3. The electronic package of claim 1, wherein the substrate adjacent to the sidewalls of the metallic layer is recessed.

4. The electronic package of claim 3, wherein the feature extends over the recessed surface of the substrate.

5. The electronic package of claim 1, wherein the feature is a trace.

6. The electronic package of claim 1, wherein the feature is a pad.

7. The electronic package of claim 1, wherein the metallic layer is a seed layer.

8. The electronic package of claim 1, wherein the substrate comprises a buildup layer over the glass layer, and wherein the metallic layer is on the buildup layer.

9. An electronic package, comprising:
a core, wherein the core comprises glass;
a via through the core, wherein a first seed layer is provided between the via and the core; and
traces over the core, wherein a second seed layer is provided between the traces and the core, and wherein sidewalls of the second seed layer are sloped.

10. The electronic package of claim 9, wherein the sidewalls of the second seed layer are sloped so that a bottom of the second seed layer is wider than a top of the second seed layer.

11. The electronic package of claim 9, wherein the via is an hourglass shaped via.

12. The electronic package of claim 9, wherein the first seed layer and the second seed layer comprise one or more of palladium, titanium, and copper.

13. The electronic package of claim 9, further comprising:
a buffer layer over the core, wherein the via passes through the buffer layer, and wherein the traces are on the buffer layer.

14. The electronic package of claim 13, wherein the via has tapered sidewalls.

15. The electronic package of claim 13, wherein the buffer layer exhibits laser induced damage on a top surface.

16. The electronic package of claim 15, wherein the buffer layer is recessed approximately 2 μm or more below the second seed layer.

17. An electronic system, comprising:
a board;
a package substrate coupled to the board, wherein the package substrate comprises:
a substrate;
a seed layer over the substrate, wherein edges of the seed layer have a non-vertical profile; and
a feature over the seed layer, wherein the feature is electrically conductive; and
a die coupled to the package substrate.

18. The electronic system of claim 17, wherein the substrate adjacent to the edges of the seed layer is recessed by approximately 2 μm or more.

19. The electronic system of claim 17, wherein the non-vertical profile is an outward slope with a top surface that is narrower than a bottom surface.

20. The electronic system of claim 17, wherein the electronic system is part of a personal computer, a server, a mobile device, a tablet, or an automobile.
